(19) United States
(12) Patent Application Publication
(10) Pub. No.: US 2016/0204134 A1
(43) Pub. Date: Jul. 14, 2016

(54) An Array Substrate Manufacturing Method, An Array Substrate And A Display Panel

(71) Applicant: Shenzhen China Star Optoelectronics Technology Co. Ltd., Shenzhen, Guangdong (CN)

(72) Inventors: Yutong HU, Shenzhen, Guangdong (CN); Xin ZHANG, Shenzhen, Guangdong (CN); Ronglei DAI, Shenzhen, Guangdong (CN)

(73) Assignee: Shenzhen China Star Optoelectronics Technology Co. Ltd., Shenzhen, Guangdong (CN)

(21) Appl. No.: 14/433,651

(22) PCT Filed: Jan. 28, 2015
(86) PCT No.: PCT/CN2015/071712

§ 371 Date: Apr. 4, 2015

(30) Foreign Application Priority Data
Jan. 13, 2015 (CN) 2015100166919

(51) Int. Cl. H01L 27/12; G02F 1/1335; G02F 1/1362; G02F 1/1343

(52) U.S. Cl. CPC H01L 27/1222; H01L 27/124; G02F 1/13439; G02F 1/133514; G02F 1/136227

(57) ABSTRACT

The present invention discloses an array substrate manufacturing method, an array substrate and a display panel, and the method comprises: forming a gate electrode and a first electrode which is transparent on the substrate; forming an isolated layer on the substrate, and covering the isolated layer on the gate electrode and the first electrode; forming a semiconductor layer on the isolated layer; forming a medium layer on the semiconductor layer, and providing a first via hole, a second via hole and a third via hole; forming a source electrode, a drain electrode, and a second electrode on the medium layer, the source electrode and the drain electrode are connected to the semiconductor layer respectively through the first via hole and the second via hole, and the second electrode is connected to the first electrode through the third via hole to form a storage capacitance; forming a third electrode which is transparent on the medium layer, and the third electrode is connected to the drain electrode to form a pixel electrode. An utilized amount of photomasks can be decreased, technical processes can be reduced and cost can be saved during the manufacturing procedures of the array substrate in the present invention by applying the aforemention method.

### FIELD OF THE INVENTION

The invention relates to display field, particularly to, an array substrate and a display panel.

### BACKGROUND OF THE INVENTION

Low Temperature Poly-silicon (refer to as LTPS) thin film transistor liquid crystal display is formed in a packaging procedure; a excimer laser as heat source produces a laser beam with a uniform energy distribution to aim on a amorphous silicon structure of a glass substrate via passing through a projecting system, and then the amorphous silicon structure of a glass substrate will turn to be a poly-silicon structure after the energy of the excimer laser is absorbed in the amorphous silicon structure of a glass substrate; all of the procedure is under 600, therefore a general glass substrate is applicable in the procedures.

Pixel layer structures of a traditional bottom-gate type LTPS are multiple, therefore a larger amount of masks is needed in procedures during manufacturing procedures that enormously increases a production cost. Take a manufacturing procedures of a traditional PMOS for example, nine masks at least is usually needed in manufacturing procedures.

Besides, in a pixel of the traditional bottom-gate type LTPS, a organic layer is often used to insulate a metal electrode and a transparent electrode to decrease a parasitic capacitance between the metal electrode and the transparent electrode; a thickness of the organic layer is always thicker; thus, a uniformity of the manufacturing procedure requires higher criteria, and a problem of uneven displaying brightness is caused usually to decrease manufacturing qualities then.

### SUMMARY OF THE INVENTION

A technical problem mainly solved by the present invention is to provide an array substrate manufacturing method of, an array substrate and a display panel, so that a photomask usage amount can be decreased, a process flow can be reduced and cost can be saved in manufacturing process.

In order to solve the aforementioned problem, a technique applied in the present invention is: providing an array substrate manufacturing method, and the method comprises: forming a gate electrode and a first electrode which is transparent on the substrate; forming an isolated layer on the substrate, and covering the gate electrode and the first electrode with the isolated layer; forming a semiconductor layer on the isolated layer; forming a medium layer on the semiconductor layer, and providing a first via hole and a second via hole at a region corresponding to the semiconductor layer, revealing the semiconductor layer on both positions of the first via hole and the second via hole, providing a third via hole in a region of the first electrode correspondingly, and revealing the first electrode on a position of the third via hole;

forming a source electrode, a drain electrode, and a second electrode on the medium layer, the source electrode and the drain electrode are connected to the semiconductor layer respectively through the first via hole and the second via hole, and the second electrode is connected to the first electrode through the third via hole to form a storage capacitance; forming a third electrode which is transparent on the medium layer, and the third electrode is connected to the drain electrode to form a pixel electrode; wherein, the gate electrode, the source electrode, the drain electrode and the second electrode are metal electrodes; the first electrode and third electrode are Indium-Tin Oxide (ITO).

Wherein, steps of forming the semiconductor layer on the isolated layer particularly is: depositing a layer of the amorphous silicon on the isolated layer to get a poly-silicon; covering a layer of photoresist on the Poly-silicon; performing illuminating to the substrate, and then exposing a portion of the photoresist which is not shielded by the gate electrode; performing etching to both the photoresist and an exposing portion of the poly-silicon; doping the Poly-silicon to form a first doped region corresponding to the first via hole and a second doped region corresponding to the second via hole to connected respectively to the source electrode and the drain electrode.

Wherein, the gate electrode is connected to a gate line.

In order to solve aforementioned technical problem, another technique program applied in the present invention is: providing an array substrate, and the array substrate comprises a substrate, and a first electrode layer, an isolated layer, a semiconductor layer, a medium layer and a second electrode layer disposed on the substrate in sequence; wherein, the first electrode layer comprises a gate electrode and a first electrode which is transparent; the second electrode layer comprises a source electrode, a drain electrode, a second electrode and a third electrode which is transparent; a first via hole and a second via hole are disposed in a region of the medium layer corresponding to the semiconductor layer to connect to the source electrode and the drain electrode respectively; a third via hole is disposed in a region of both the medium layer and isolated layer corresponding to the first electrode, so that the first electrode can connect to the second electrode to form a storage capacitance; the third electrode is connected to the drain electrode to form a pixel electrode.

Wherein, the semiconductor layer is manufactured by doping a poly-silicon, and forms a first doped region and a second doped region; the first doped region and the second doped region respectively corresponding to the first via hole and the second via hole are connected to the source electrode and the drain electrode.

Wherein, the gate electrode, the source electrode, the drain electrode and the second electrode are metal electrodes; the gate electrode is connected to a gate line.

Wherein, the first electrode and the third electrode are Indium-Tin Oxide(ITO).

In order to solved the aforementioned technical problem, another technique applied in the present invention is: providing a display panel, and the display panel comprises a color filter substrate, an array substrate and a liquid crystal layer between the color filter substrate and the array substrate, and is characterized in that the array substrate comprises a substrate and a first electrode layer, an isolated layer, a semiconductor layer, a medium layer and a second electrode layer disposed on the substrate in sequence;

wherein, the first electrode layer comprises a gate electrode and a first electrode which is transparent; the second electrode layer comprises a source electrode, a drain electrode, a second electrode and a third electrode which is transparent; a first via hole and a second via hole are disposed in a region of the medium layer corresponding to the semiconductor layer, so that the semiconductor layer can connect to the source electrode and the drain electrode respectively;

a third via hole is disposed in a region of both the medium layer and isolated layer corresponding to the first electrode, so that the first electrode can connect to the second electrode to form a storage capacitance; the third electrode is connected the drain electrode to form a pixel electrode.

Wherein, the semiconductor layer is manufactured by doping a poly-silicon, and then forms a first doped region and a second doped region; the first doped region and the second doped region respectively corresponding to the first via hole and the second via hole are connected to the source electrode and the drain electrode. Wherein, the gate electrode, the source electrode, the drain electrode and the second electrode are metal electrodes; the gate electrode is connected to a gate line. Wherein, the first electrode and the third electrode are Indium-Tin Oxide (ITO).

The beneficial efficiencies of the present invention are: to distinguish from situations in the art, the first electrode is disposed on the substrate in the present invention to prevent applying a quite thick isolation layer when disposing the first electrode on the semiconductor layer to separate the first electrode from the source electrode and the drain electrode, and when disposing the third electrode on the first electrode, using a quite thick isolation layer for separation causes a problem of uneven displaying brightness in the traditional technologies; thus displaying efficiencies can be increased, and only seven photomasks needed in the manufacturing procedures comparing to nine photomasks utilized in traditional technologies is saving two photomasks, therefore manufacturing procedures are simplified and cost is reduced.

### BRIEF DESCRIPTION OF THE DRAWINGS

FIG. 1 is a flowchart of a first embodiment illustrating an array substrate manufacturing method of the present invention;

FIG. 2 is a structural schematic view of step 101 according to the first embodiment illustrating the array substrate manufacturing method of the present invention;

FIG. 3 is a structural schematic view of step 102 according to the first embodiment illustrating the array substrate manufacturing method of the present invention;

FIG. 4 is a structural schematic view of step 103 according to the first embodiment illustrating the array substrate manufacturing method of the present invention;

FIG. 5 is a structural schematic view of step 104 according to the first embodiment illustrating the array substrate manufacturing method of the present invention;

FIG. 6 is a structural schematic view of step 105 according to a first embodiment illustrating the array substrate manufacturing method of the present invention;

FIG. 7 is a structural schematic view of step 106 according to the first embodiment illustrating the array substrate manufacturing method of the present invention;

FIG. 8 is a flowchart of a second embodiment illustrating an array substrate manufacturing method of the present invention;

FIG. 9 is a structural schematic view of step 801 according to the second embodiment illustrating the array substrate manufacturing method of the present invention;

FIG. 10 is a structural schematic view of step 802 according to the second embodiment illustrating the array substrate manufacturing method of the present invention;

FIG. 11 is a structural schematic view of step 803 according to the second embodiment illustrating the array substrate manufacturing method of of the present invention;

FIG. 12 is a structural schematic view of step 805 according to the second embodiment illustrating the array substrate manufacturing method of the present invention;

FIG. 13 is a structural schematic view of the array substrate according to an embodiment of the present invention;

FIG. 14 is a schematic view of a display panel according to an embodiment of the present invention.

### DETAILED DESCRIPTION OF THE EMBODIMENT

Refer to FIG. 1, a flowchart of a first embodiment illustrating an array substrate manufacturing method of the present invention, the method comprises:

step 101: forming a gate electrode 202 and a first electrode 203 which is transparent on the substrate 201;

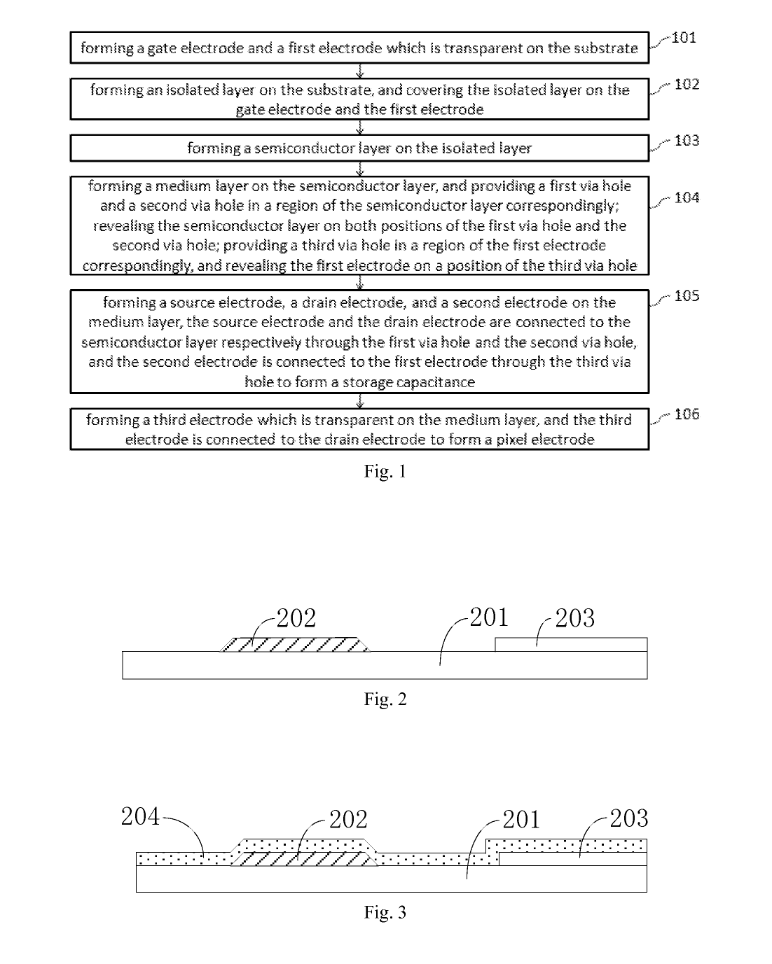

As shown in FIG. 2, a glass is applied in a substrate 201; after cleaning and drying the substrate 201 substrate, the gate electrode 202 can be formed on the glass substrate 201 by vacuum sputtering coating, a gate material can be one of Pt, Ru, Au, Ag, Mo, Cr, Al, Ta, Ti, W or an alloy of multiple metals, and the gate electrode 202 is used in connecting to a gate line; moreover, a transparent conductive layer is sputtered as the first electrode 203 on the glass substrate 201 by depositing, ex: ITO (Indium Tin Oxide), AZO (Aluminum doped Zinc Oxide) and etc., and the gate electrode 202 and the first electrode are not interfering to each other via being manufactured in sequence without standard orders.

In that case, the gate electrode 202 and the first electrode 203 are patterned by using respectively a first photomask and a second photomask.

Step 102: forming an isolated layer 204 on the substrate 201, and covering the isolated layer 204 on the gate electrode 202 and the first electrode 203;

As shown in FIG. 3, the isolated layer 204 can be a silicon oxide (SiOx) layer and a silicon nitride (SiNx), or can be formed by stacking a silicon oxide (SiOx) layer and a silicon nitride (SiNx) layer and, and both of them are formed by a method of chemical deposition on the substrate 201 and are covering on the gate electrode 202 and the first electrode 203 to provide insulation performance.

In that case, the isolated layer 204 is patterned by using a third photomask.

Step 103: forming a semiconductor layer 205 on the isolated layer 204.

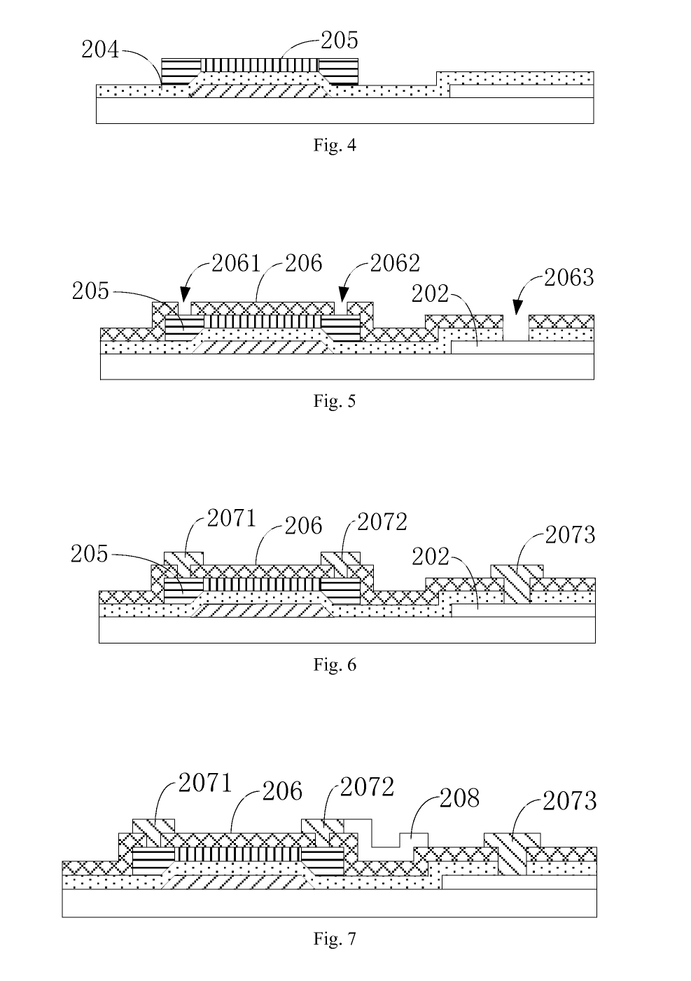

As shown in FIG. 4, the semiconductor layer 205 can be a structure of P-MOS, N-MOS or C-MOS formed by doping a amorphous silicon or a poly-silicon.

In that case, the semiconductor layer 205 is patterned by using a fourth photomask.

Step 104: forming a medium layer 206 on the semiconductor layer 205, and providing a first via hole 2061 and a second via hole 2062 in a region of the semiconductor layer correspondingly, and then revealing the semiconductor layer 205 on both positions of the first via hole 2061 and the second via hole 2062; providing a third via hole 2063 in a region of the first electrode 202 correspondingly, and revealing the first electrode 202 on a position of the third via hole 2063;

As shown in FIG. 5, the medium layer 206 is performing insulation to the semiconductor layer 206 and a following-up electrode layer by using interlayer dielectrics (ILD) as an insulating material.

In that case, the process of providing via hole to the medium layer 206 is by using a fifth photomask.

Step 105: forming a source electrode 2071, a drain electrode 2072, and a second electrode 2073 on the medium layer 206, the source electrode 2071 and the drain electrode 2072 are connected to the semiconductor layer 205 respectively through the first via hole 2061 and the second via hole 2062, and the second electrode 2073 is connected to the first electrode 202 through the third via hole 2063 to form a storage capacitance;

The source electrode 2071, the drain electrode 2072 and the second electrode 2073 are one of Pt, Ru, Au, Ag, Mo, Cr, Al, Ta, Ti, W or an alloy of multiple metals formed by a method of coating film and etc.

In this case, the source electrode 2071 and the drain electrode 2072 are patterned by using a sixth photomask respectively.

Step 106: forming a third electrode 208 which is transparent on the medium layer 206, and the third electrode 208 is connected to the drain electrode 2072 to form a pixel electrode.

A material of the third electrode 208 is the same as the material of the first electrode 202 that a transparent conductive film of ITO (Indium Tin Oxide), AZO (Aluminum doped Zinc Oxide) and etc. can also be applied in.

In this case, the third electrode 208 is patterned by using a seventh photomask.

In order to distinguish from the present technology, the first electrode is disposed on the substrate in the present embodiment to prevent applying a quite thick isolation layer when disposing the first electrode on the semiconductor layer to separate the first electrode from the source electrode and the drain electrode, and when disposing the third electrode on the first electrode, using a quite isolation layer for separation causes a problem of uneven displaying brightness in the traditional technologies; thus displaying efficiencies can be increased, and only seven photomasks needed in the manufacturing procedures comparing to nine photomasks utilized in traditional technologies is saving two photomasks, therefore manufacturing procedures are simplified and cost is reduced.

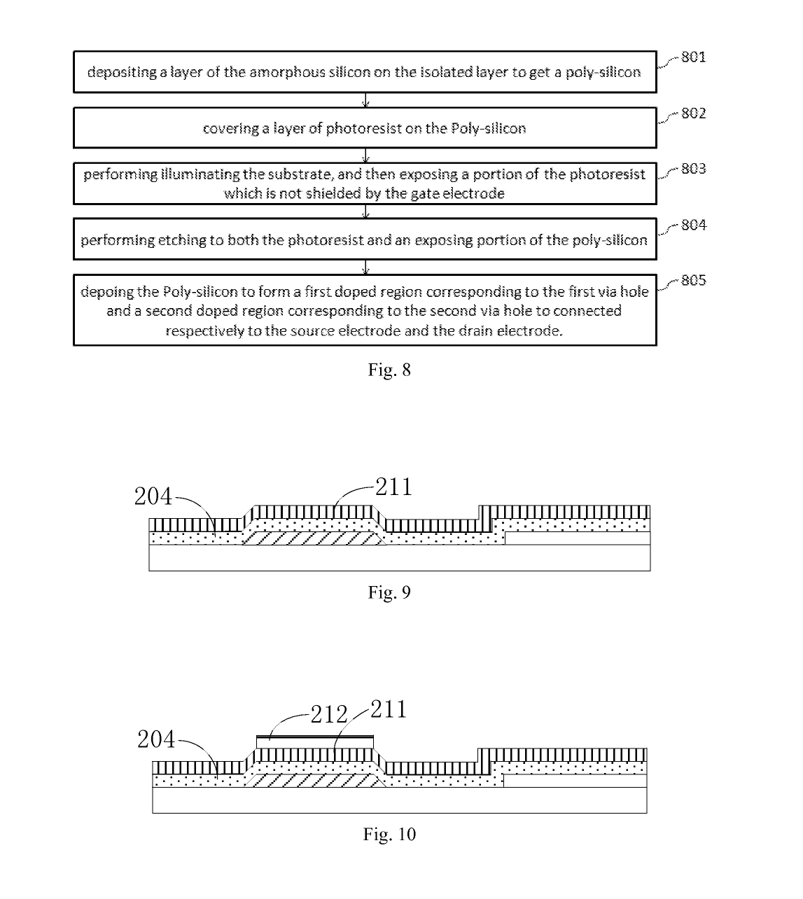

Refer to FIG. 8, a flowchart of a second embodiment illustrating an array substrate manufacturing method of the present invention, and the method comprises:

step 801: depositing a layer of the amorphous silicon on the isolated layer 204 to get a poly-silicon 211;

as shown in FIG. 9, depositing a layer of the amorphous silicon (a-Si) on the isolated layer 204, and after a laser passes through the projecting system via utilizing excimer laser as a heat source, an excimer laser with even energy distribution will be occurred and projected to the amorphous silicon layer; the amorphous silicon layer will turn into poly-silicon 211 structure after absorbing energy of the excimer laser, and a whole processing procedure is accomplished under 600.

Step 802: covering a layer of photoresist 212 on the Poly-silicon 211;

as shown in FIG. 10, the photoresist 212 is a negative photoresist.

Step 803: performing illuminating the substrate, and then exposing a portion of the photoresist 212 which is not shielded by the gate electrode 202;

step 804: performing etching to both the photoresist 212 and an exposing portion of the poly-silicon 211;

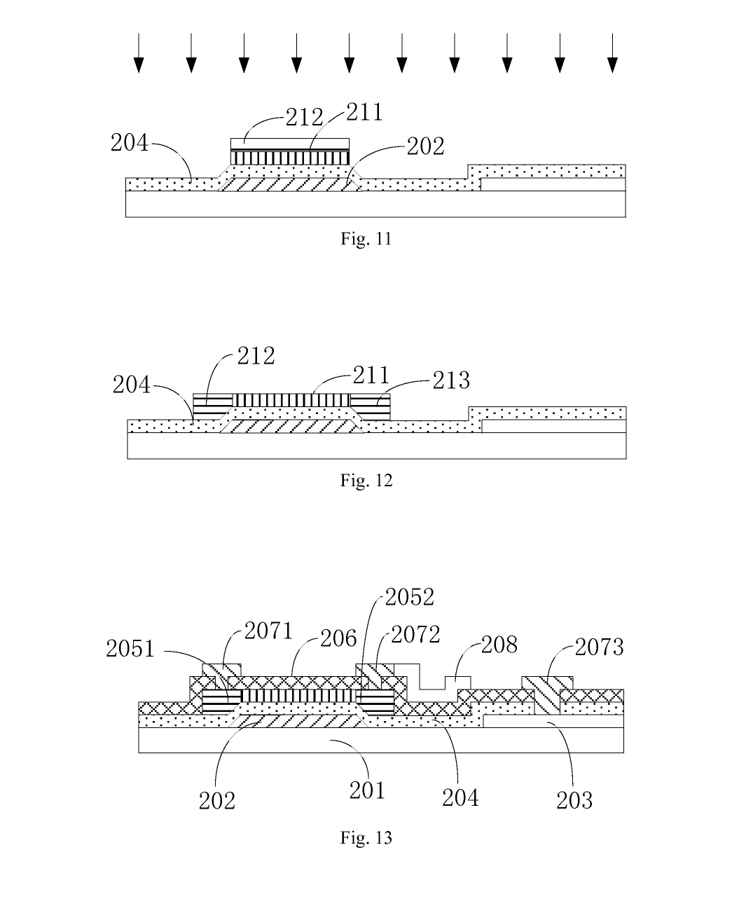

as shown in FIG. 11, the photoresist 212 on the gate electrode 202 correspondingly cannot be exposed because being shielded by the gate electrode 202, and then performing etching to poly-silicon and photoresist of the exposing portion.

Step 805: doping the Poly-silicon 211 to form a first doped region 212 corresponding to the first via hole and a second doped region 213 corresponding to the second via hole to connected respectively to the source electrode and the drain electrode.

As shown in FIG. 12, the doping is P+ doping or N+ doping, therefore the semiconductor layer is formed into a structure of P-MOS, N-MOS or C-MOS.

The embodiment method is only detail steps in the step 103 of the first embodiment, but not the whole method in manufacturing an array substrate totally, and before and after the step further comprises other steps as comprising in the first embodiment.

In order to distinguish from the present technology, the first electrode is disposed on the substrate in the present embodiment to prevent applying a quite thick isolation layer when disposing the first electrode on the semiconductor layer to separate the first electrode from the source electrode and the drain electrode, and when disposing the third electrode on the first electrode, using a quite isolation layer for separation causes a problem of uneven displaying brightness in the traditional technologies; thus displaying efficiencies can be increased, and only seven photomasks needed in the manufacturing procedures comparing to nine photomasks utilized in traditional technologies is saving two photomasks, therefore manufacturing procedures are simplified and cost is reduced.

Refer to FIG. 13, a structural schematic view of the array substrate according to an embodiment of the present invention; the array substrate comprises a substrate 201 and a first electrode layer, an isolated layer 204, a semiconductor layer, a medium layer 206 and a second electrode layer disposed on the substrate in sequence;

wherein, the first electrode layer comprises a gate electrode 202 and a first electrode 203 which is transparent; the second electrode layer comprises a source electrode 2071, a drain electrode 2072, a second electrode 2073 and a third electrode 208 which is transparent a first via hole and a second via hole are disposed in a region of the medium layer 206 corresponding to the semiconductor layer, so that the semiconductor layer can connect to the source electrode 2071 and the drain electrode 2072 respectively; a third via hole is disposed in a region of both the medium layer 206 and isolated layer 204 corresponding to the first electrode 203, so that the first electrode 203 can connect to the second electrode 2073 to form a storage capacitance; the third electrode 208 is connected the drain electrode 2072 to form a pixel electrode.

Wherein, the semiconductor layer is manufactured by doping a poly-silicon, and then forms a first doped region 2051 and a second doped region 2052; the first doped region 2051 and the second doped region 2052 respectively corresponding to the first via hole and the second via hole are connected to the source electrode 2071 and the drain electrode 2072.

Wherein, the gate electrode 202 is connected to a gate line.

Wherein, the gate electrode 202, the source electrode 2071, the drain electrode 2072 and the second electrode 2073 are metal electrodes.

wherein, the first electrode 203 and the third electrode 208 are Indium-Tin Oxide (ITO).

Products of the manufacturing method is based on the aforementioned array substrate in the present embodiment, thus it is not further described in detail here because the embodiment methods are similar.

In order to distinguish from the present technology, the first electrode is disposed on the substrate in the present embodiment to prevent applying a quite thick isolation layer when disposing the first electrode on the semiconductor layer to separate the first electrode from the source electrode and the drain electrode, and when disposing the third electrode on the first electrode, using a quite isolation layer for separation causes a problem of uneven displaying brightness in the traditional technologies; thus displaying efficiencies can be increased, and only seven photomasks needed in the manufacturing procedures comparing to nine photomasks utilized in traditional technologies is saving two photomasks, therefore manufacturing procedures are simplified and cost is reduced.

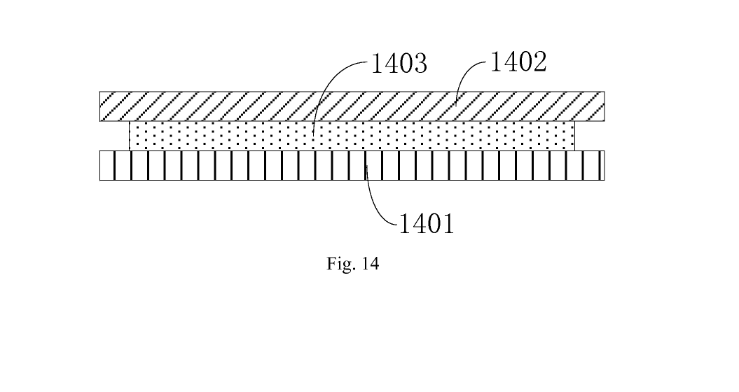

Refer to FIG. 14, a schematic view of a display panel according to an embodiment of the present invention; display panel comprises a color filter substrate 1041, an array substrate 1042 and a liquid crystal layer 2043 between the color filter substrate 2041 and the array substrate 1042, and is characterized in that the array substrate 1041 is like the aforemention array substrate of the aforementioned embodiment thus is not further described in detail here.

In order to distinguish from the present technology, the first electrode is disposed on the substrate in the present embodiment to prevent applying a quite thick isolation layer when disposing the first electrode on the semiconductor layer to separate the first electrode from the source electrode and the drain electrode, and when disposing the third electrode on the first electrode, using a quite isolation layer for separation causes a problem of uneven displaying brightness in the traditional technologies; thus displaying efficiencies can be increased, and only seven photomasks needed in the manufacturing procedures comparing to nine photomasks utilized in traditional technologies is saving two photomasks, therefore manufacturing procedures are simplified, cost is reduced and the displaying efficiency is even better.

What described are merely preferable embodiment of the disclosure and are not intended to limit the scope of the disclosure. All equivalent structures or equivalent flow variations made using content of the specification and accompanying drawings of the disclosure, or direct or indirect application to another related technical field, likewise fall within the scope of the disclosure.

1. An array substrate manufacturing method, wherein, the method comprises:
forming a gate electrode and a first electrode which is transparent on the substrate;
forming an isolated layer on the substrate, and covering the isolated layer on the gate electrode and the first electrode;
forming a semiconductor layer on the isolated layer; forming a medium layer on the semiconductor layer, and providing a first via hole and a second via hole in a region of the semiconductor layer correspondingly; revealing the semiconductor layer on both positions of the first via hole and the second via hole; providing a third via hole in a region of the first electrode correspondingly, and revealing the first electrode on a position of the third via hole;
forming a source electrode, a drain electrode, and a second electrode on the medium layer, the source electrode and the drain electrode are connected to the semiconductor layer respectively through the first via hole and the second via hole, and the second electrode is connected to the first electrode through the third via hole to form a storage capacitance;
forming a third electrode which is transparent on the medium layer, and the third electrode is connected to the drain electrode to form a pixel electrode;
wherein, the gate electrode, the source electrode, the drain electrode and the second electrode are metal electrodes;
the first electrode and third electrode are Indium-Tin Oxide (ITO).

2. The method according to the claim 1, wherein, steps of forming the semiconductor layer on the isolated layer particularly is:
depositing a layer of the amorphous silicon on the isolated layer to get a poly-silicon;
covering a layer of photoresist on the Poly-silicon;
performing illuminating the substrate, and then exposing a portion of the photoresist which is not shielded by the gate electrode;
performing etching to both the photoresist and an exposing portion of the poly-silicon;
doping the Poly-silicon to form a first doped region corresponding to the first via hole and a second doped region corresponding to the second via hole to connected respectively to the source electrode and the drain electrode.

3. The method according to the claim 1, wherein, the gate electrode is connected to a gate line.

4. An array substrate, wherein, the array substrate comprises a substrate, and a first electrode layer, an isolated layer, a semiconductor layer, a medium layer and a second electrode layer disposed on the substrate in sequence;
wherein, the first electrode layer comprises a gate electrode and a first electrode which is transparent;
the second electrode layer comprises a source electrode, a drain electrode, a second electrode and a third electrode which is transparent;
a first via hole and a second via hole are disposed in a region of the medium layer corresponding to the semiconductor layer to connect to the source electrode and the drain electrode respectively;
a third via hole is disposed in a region of both the medium layer and isolated layer corresponding to the first electrode, so that the first electrode can connect to the second electrode to form a storage capacitance;
the third electrode is connected to the drain electrode to form a pixel electrode.

5. The array substrate according to the claim 4, wherein, the semiconductor layer is manufactured by doping a poly-silicon, and forms a first doped region and a second doped region;
the first doped region and the second doped region respectively corresponding to the first via hole and the second via hole are connected to the source electrode and the drain electrode.

6. The array substrate according to the claim 4, wherein, the gate electrode, the source electrode, the drain electrode and the second electrode are metal electrodes;
the gate electrode is connected to a gate line.

7. The array substrate according to the claim 4, wherein, the first electrode and the third electrode are Indium-Tin Oxide (ITO).

8. A display panel comprises a color filter substrate, an array substrate and a liquid crystal layer between the color filter substrate and the array substrate, wherein, the array substrate comprises a substrate and a first electrode layer, an isolated layer, a semiconductor layer, a medium layer and a second electrode layer disposed on the substrate in sequence;
wherein, the first electrode layer comprises a gate electrode and a first electrode which is transparent;
the second electrode layer comprises a source electrode, a drain electrode, a second electrode and a third electrode which is transparent;
a first via hole and a second via hole are disposed in a region of the medium layer corresponding to the semiconductor layer, so that the semiconductor layer can connect to the source electrode and the drain electrode respectively;
a third via hole is disposed in a region of both the medium layer and isolated layer corresponding to the first electrode, so that the first electrode can connect to the second electrode to form a storage capacitance;
the third electrode is connected the drain electrode to form a pixel electrode.

9. The display panel according to the claim 8, wherein, the semiconductor layer is manufactured by doping a poly-silicon, and then forms a first doped region and a second doped region;
the first doped region and the second doped region respectively corresponding to the first via hole and the second via hole are connected to the source electrode and the drain electrode.

10. The display panel according to the claim 8, wherein, the gate electrode, the source electrode, the drain electrode and the second electrode are metal electrodes;
the gate electrode is connected to a gate line.

11. The display panel according to the claim 8, wherein, the first electrode and the third electrode are Indium-Tin Oxide (ITO).
